(19) United States
(12) Patent Application Publication
(10) Pub. No.: US 2013/0118575 A1
(43) Pub. Date: May 16, 2013

(54) CIGS TYPE SOLAR CELL AND ELECTRODE-ATTACHED GLASS SUBSTRATE THEREFOR

(71) Applicant: Asahi Glass Company, Limited, Chiyoda-ku (JP)

(72) Inventors: Takeshi OKATO, Chiyoda-ku (JP); Hidefumi Odaka, Chiyoda-ku (JP)

(73) Assignee: Asahi Glass Company, Limited, Chiyoda-ku (JP)

(21) Appl. No.: 13/718,306

(22) Filed: Dec. 18, 2012

Related U.S. Application Data
(63) Continuation of application No. PCT/JP2011/063615, filed on Jun. 14, 2011.

(30) Foreign Application Priority Data
Jun. 18, 2010 (JP) 2010-139923

(51) Int. Cl. H01L 31/0224

(52) U.S. Cl. CPC H01L 31/022425
USPC 136/256

(57) ABSTRACT

To provide a CIGS type solar cell capable of diffusing an alkali metal in a CIGS layer without increasing steps of its manufacturing process or complicating its layer structure. A CIGS type solar cell comprising a glass substrate, a rear surface electrode layer provided on the glass substrate, a CIGS layer provided on the rear surface electrode layer, a buffer layer provided on the CIGS layer and a transparent front surface electrode layer provided on the buffer layer, wherein the rear surface electrode layer contains Mo (molybdenum) and W (tungsten), and the total W content in the rear surface electrode layer is at most 50 mol %.

### FIELD OF INVENTION

The present invention relates to a CIGS type solar cell and a member constituting such a solar cell.

### BACKGROUND OF INVENTION

A CIGS (Copper Indium Gallium DiSelenide) type solar cell shows a high energy conversion efficiency, and shows little deterioration of the efficiency due to light-irradiation. For this reason, research and development of such a solar cell is being conducted in various companies or research agencies.

A typical CIGS type solar cell is constituted by a substrate of e.g. a glass, and a Mo (molybdenum) electrode, a CIGS layer, a buffer layer and a ZnO (zinc oxide) electrode laminated in this order on the substrate.

In such a construction, the buffer layer functions as a n-type semiconductor layer, and the CIGS layer functions as a p-type semiconductor layer. Accordingly, when the CIGS layer (pn junction) is irradiated with light, photoexcitation of electrons occurs to produce photovoltaic power. Accordingly, by light-irradiation of a solar cell, it is possible to take out a direct current from electrodes to the outside.

Here, the CIGS layer is usually composed of a compound such as Cu(In,Ga)Se₂. Further, it is known that in such a CIGS layer, due to the presence of an alkali metal such as Na (sodium), the defect density is decreased and the carrier concentration is increased. In a case of employing a CIGS layer having a high carrier density, the energy conversion efficiency of a solar cell is improved.

Accordingly, it is proposed to provide a layer containing an alkali metal such as Na (sodium) between a Mo electrode and a CIGS layer (Patent Documents 1 and 2). In this case, during a process for producing a solar cell, it is possible to diffuse an alkali metal from a layer containing the alkali metal into the CIGS layer. Further, by this diffusion, it is possible to further improve the energy conversion efficiency of the solar cell.

### PRIOR ART DOCUMENTS

### Patent Documents

Patent Document 1: JP-A-2004-079858
Patent Document 2: JP-A-2004-140307

### SUMMARY OF INVENTION

### Technical Problem

However, there is such a problem that in a process of producing a solar cell, extra steps are required and the layer structure becomes complicated, when the above-described method is employed wherein a layer containing an alkali metal is additionally provided. Further, in the usual case, many of such layers containing an alkali metal disclosed in Patent Documents 1 and 2 are hygroscopic or soluble in water, and there is a problem that such a layer is poor in durability.

Further, in a case of using a large area substrate such as for solar cells, it is suitable to employ a sputtering method since it is thereby possible to form a film with high uniformity over a large area. Among sputtering methods, particularly, DC sputtering wherein a direct current is used is most suitable for forming a film having a large area. However, a conventional target material of a compound containing Na as an element of group 1 in the periodic table is an insulating material, and thus only RF sputtering can be applied to such a target material.

Further, there is such a problem that when sputtering is applied to a compound containing a group 1 element, the group 1 element remains as contamination on the inner wall of the chamber, and thus it is difficult to use the same chamber for film forming of a member to be applied to a device which dislikes group 1 elements.

The present invention has been made in view of the above problems, and it is to provide a CIGS type solar cell capable of diffusing an alkali metal into a CIGS layer without increasing steps of its manufacturing process or complicating its layer structure and to provide a member constituting such a solar cell.

### Solution to Problem

The present invention provides a CIGS type solar cell comprising a glass substrate, a rear surface electrode layer provided on the glass substrate, a CIGS layer provided on the rear surface electrode layer, a buffer layer provided on the CIGS layer and a transparent front surface electrode layer provided on the buffer layer, wherein the rear surface electrode layer contains Mo (molybdenum) and W (tungsten), and the total W content in the rear surface electrode layer is at most 50 mol %.

In the solar cell of the present invention, the total W content in the rear surface electrode layer may be at least 1 mol %.

Further, in the solar cell of the present invention, the rear surface electrode layer may be a laminated film comprising a Mo film and a Mo—W alloy film or a laminated film comprising at least two types of Mo—W alloy films having different W contents.

Further, in the solar cell the present invention, the rear surface electrode layer may have a thickness within a range of from 20 nm to 1,500 nm.

Further, in the solar cell of the present invention, the glass substrate may be a silica glass substrate comprising, based on oxides, from 50 mass % to 75 mass % of SiO₂, said glass substrate containing from 2 mass % to 15 mass % of Na₂O and from 0 mass % to 10 mass % of K₂O.

Further, in the solar cell of the present invention, the glass substrate may comprise, based on oxides, from 1 mass % to 15 mass % of Al₂O₃, from 0 mass % to 2 mass % of B₂O₃, from 0 mass % to 10 mass % of MgO, from 0 mass % to 11 mass % of CaO, from 0 mass % to 12 mass % of SrO, from 0 mass % to 10 mass % of BaO, from 0 mass % to 6 mass % of ZrO₂, from 50 mass % to 75 mass % of SiO₂, from 2 mass % to 15 mass % of Na₂O and from 0 mass % to 10 mass % of K₂O.

Further, the present invention provides an electrode-attached glass substrate for a CIGS type solar cell, which comprises a glass substrate and a rear surface electrode layer provided on a first surface of the glass substrate, wherein the rear surface electrode layer contains Mo (molybdenum) and W (tungsten), and the total W content in the rear surface electrode layer is at most 50 mol %.

Further, in the electrode-attached glass substrate of the present invention, the total W content in the rear surface electrode layer may be at least 1 mol %.

Further, in the electrode-attached glass substrate of the present invention, the rear surface electrode layer may be a laminated film comprising a Mo film and a Mo—W alloy film or a laminated film comprising at least two types of Mo—W alloy films having different W contents.

Further, in the electrode-attached glass substrate of the present invention, the rear surface electrode layer may have a thickness within a range of from 20 nm to 1,500 nm.

Further, in the electrode-attached glass substrate of the present invention, the glass substrate may be a silica glass substrate comprising, based on oxides, from 50 mass % to 75 mass % of SiO₂, said glass substrate containing from 2 mass % to 15 mass % of Na₂O and from 0 mass % to 10 mass % of K₂O.

Further, in the electrode-attached glass substrate of the present invention, the glass substrate may comprise, based on oxides, from 1 mass % to 15 mass % of Al₂O₃, from 0 mass % to 2 mass % of B₂O₃, from 0 mass % to 10 mass % of MgO, from 0 mass % to 11 mass % of CaO, from 0 mass % to 12 mass % of SrO, from 0 mass % to 10 mass % of BaO, from 0 mass % to 6 mass % of ZrO₂, from 50 mass % to 75 mass % of SiO₂, from 2 mass % to 15 mass % of Na₂O and from 0 mass % to 10 mass % of K₂O.

### Advantageous Effects of Invention

According to the present invention, it is possible to provide a CIGS type solar cell capable of diffusing an alkali metal into a CIGS layer without increasing steps of its manufacturing process or complicating its layer structure. Further, it becomes possible to provide a member constituting such a solar cell.

### BRIEF DESCRIPTION OF DRAWINGS

FIG. 1 is a cross-sectional view schematically illustrating a construction of a conventional CIGS type solar cell.

FIG. 2 is a cross-sectional view schematically illustrating an example of a construction of the CIGS type solar cell of the present invention.

FIG. 3 is a chart showing measurement results of Na diffusion behavior with respect to samples No. 1 to No. 6.

FIG. 4 is a chart showing measurement results of specific resistance with respect to samples No. 3 to No. 6.

FIG. 5 is a chart showing measurement results of Na diffusion behavior with respect to samples No. 7 and No. 8.

FIG. 6 is a chart showing measurement results of K diffusion behavior with respect to samples No. 7 and No. 8.

### DETAILED DESCRIPTION OF INVENTION

Now, the present invention will be described with reference to drawings.

First in order to make the characteristics of the present invention more easily understandable, the construction of a conventional CIGS type solar cell will be briefly described.

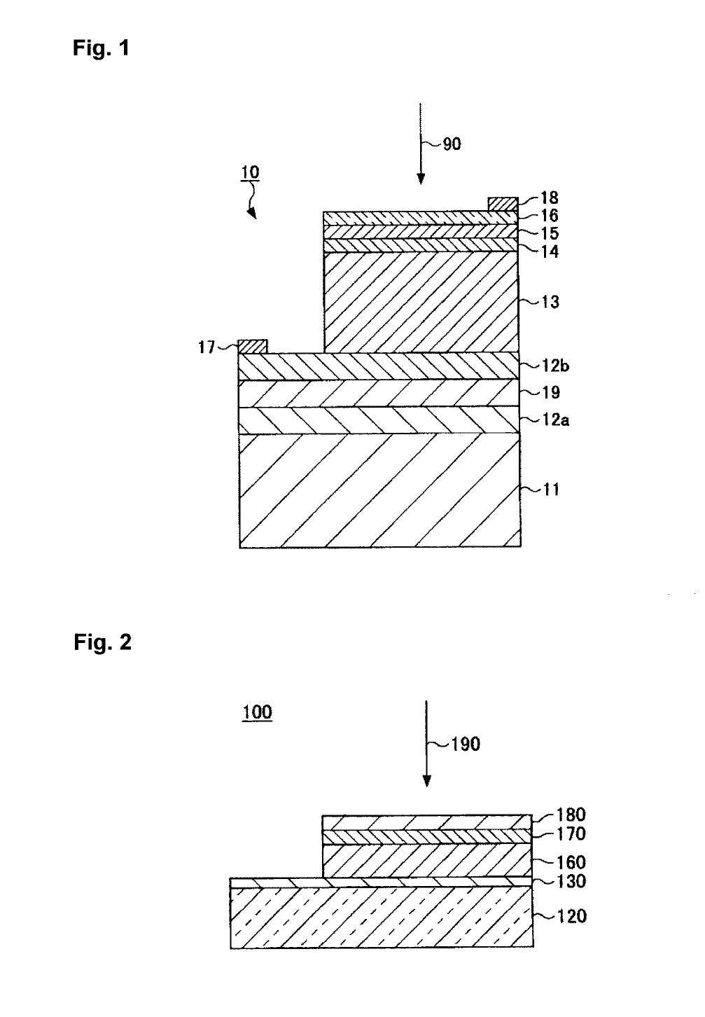

FIG. 1 is a cross-sectional view schematically illustrating a construction of a conventional CIGS type solar cell.

As shown in FIG. 1, a conventional CIGS type solar cell 10 is constituted by an insulative substrate 11, a first conductive layer 12a, a layer containing an alkali metal (alkali metal supply layer) 19, a second conductive layer 12b, a light-absorber layer 13, a first semiconductor layer 14, a second semiconductor layer 15 and a transparent conductive layer 16, which are laminated in this order. Further, usually, the solar cell 10 has retrieving electrodes 17 and 18. Here, an arrow 90 indicates an incident direction of light into the solar cell 10.

The first conductive layer 12a and the second conductive layer 12b are each composed of Mo (molybdenum) and functions as a positive electrode of the solar cell 10. Meanwhile, the transparent conductive layer 16 is composed of e.g. ZnO (zinc oxide) and functions as a negative electrode of the solar cell 1.

The first semiconductor layer 14 and the second semiconductor layer 15 are also called buffer layers, which have a function of forming a high resistance layer between the light-absorber layer 13 and the transparent conductive layer 16 to reduce a shuntpass of the solar cell.

The light-absorber layer 13 is usually composed of a compound such as Cu(In,Ga)Se₂. Here, since the light-absorber layer 13 is usually also called a CIGS layer, hereinafter this layer is referred to as “CIGS layer 13”.

The alkali metal supply layer 19 is provided to supply an alkali metal to the CIGS layer 13. The alkali metal supply layer 19 is composed of, for example, a compound such as Na₂S, Na₂Se, NaCl or NaF. It is known that in the CIGS layer 13, the defect density is reduced and the carrier concentration is increased by diffusion of an alkali metal such as Na (sodium). Accordingly, when the alkali metal supply layer 19 is provided in the vicinity of the CIGS layer 13, an alkali metal moves from the alkali metal supply layer 19 toward the CIGS layer 13, whereby the defect density is decreased and the carrier concentration is increased in the CIGS layer 13. Further, the energy conversion efficiency of the solar cell 10 is thereby improved.

In such a construction of the solar cell 10, the buffer layers 14 and 15 function as n-type semiconductor layers, and the CIGS layer 13 functions as a p-type semiconductor layer. Accordingly, when light is incident into the CIGS layer 13 (pn junction), photoexcitation of electrons occurs to produce photovoltaic power. Accordingly, by irradiating the solar cell 10 with light, it is possible to take out a direct current to the outside via the retrieving electrode 17 connected to the first conductive layer 12a and the second conductive layer 12b (positive electrodes) and the retrieving electrode 18 connected to the transparent conductive layer 16 (negative electrode).

However, in order to produce the CIGS type solar cell 10 having such a construction, it is necessary to provide, for example, an alkali metal supply layer 19, which is not directly involved in generating electricity by the solar cell 10, and two conductive layers 12a and 12b, that is, extra steps are required. Further, there is such a problem that the layer structure thereby becomes complicated.

Further, in the usual case, many of the alkali metal supply layers 19 having the above composition are hygroscopic or soluble in water, and there is a problem that the durability is poor.

Further, in a case of using a large area substrate such as for solar cells, it is suitable to employ a sputtering method since it is thereby possible to form a film with high uniformity over a large area. Among sputtering methods, particularly, DC sputtering wherein a direct current is used is most suitable for forming a film having a large area. However, a conventional target material of a compound containing Na as a group 1 element is an insulating material, and thus only RF sputtering can be applied to such a target material.

Further, there is such a problem that when sputtering is applied to a compound containing a group 1 element, the group 1 element remains as contamination on the inner wall of the chamber, and thus it is difficult to use the same chamber for film forming of a member to be applied to a device which dislikes group 1 elements.

In contrast, according to the present invention, as described in detail hereinafter, it is possible to provide a CIGS type solar cell capable of diffusing a desired amount of an alkali metal into a CIGS layer without increasing steps of its manufacturing process or complicating its layer structure.

Now, the construction of the CIGS type solar cell of the present invention will be described in detail with reference to drawings.

FIG. 2 is a cross-sectional view schematically illustrating an example of a CIGS type solar cell 100 of the present invention.

As shown in FIG. 2, the CIGS type solar cell 100 of the present invention is constituted by a glass substrate 120, a rear surface electrode layer 130, a CIGS layer 160, a buffer layer 170 and a transparent front surface electrode layer 180, which are laminated in this order. Here, although not shown in the figure, besides the above components, the solar cell 100 usually has retrieving portions such as the retrieving electrodes 17 and 18 shown in FIG. 1 electrically connected with the electrode layers. An arrow 190 shows incident direction of light into the CIGS type solar cell 100.

The glass substrate 120 contains at least one alkali metal selected from Li (lithium), Na (sodium) and K (potassium).

The rear surface electrode layer 130 contains Mo (molybdenum) and W (tungsten), and the total W content: (W/(Mo+W))×100 is at most 50 mol %. Usually, the rear surface electrode layer 130 is provided in the form of a Mo—W alloy.

According to knowledge of the present inventors, in a case where the rear surface electrode layer 130 contains both Mo and W, the amount of the alkali metal to be diffused into the CIGS layer 160 from the glass substrate 120 may be relatively easily controlled by adjusting the total W content. For example, according to knowledge of the present inventors, when the total W content is within a range of from 0 mol % to 50 mol %, particularly within a range of from 1 mol % to 50 mol %, as the total W content increases, the amount of the alkali metal diffused from the glass substrate 120 tends to increase, and when the total W content is within a range of from 50 mol % to 100 mol %, as the total W content increases, the amount of the alkali metal diffused from the glass substrate 120 tends to decrease.

Accordingly, taking advantage of such a behavior, it is possible to relatively easily diffuse a desired amount of the alkali metal from the glass substrate 120 into the CIGS layer 160.

Further, according to knowledge of the present inventors, in a case where the rear surface electrode layer 130 is composed as a laminated film of at least two layers, and at least one layer contains both Mo and W, it is possible to relatively easily control the amount of the alkali metal to be diffused from the glass substrate 120 into the CIGS layer 160 by adjusting the thickness ratio of the respective layers. For example, when using a Mo—W alloy film having a W content of 50 mol % and having high performance of diffusing an alkali metal and a Mo film having low performance of diffusing Na which are laminated, as a result, the diffused amount of the alkali metal will be intermediate between the diffusion amounts obtained when the respective films are used as single layers.

Accordingly, taking advantage of such a behavior, it is possible to relatively easily diffuse a desired amount of the alkali metal from the glass substrate 120 into the CIGS layer 160.

In the CIGS layer 160 supplied with the alkali metal, the defect density is reduced and the carrier concentration is increased. Accordingly, it is expected that the solar cell 100 of the present invention provides high energy conversion efficiency.

Further, in the method of supplying an alkali metal as in the present invention, since it is possible to utilize the alkali metal contained in the glass substrate 120 as the alkali metal to be diffused, the conventional alkali metal supply layer is not required to be provided. Accordingly, when a solar cell having the construction of the present invention is produced, such problems will not arise that extra steps are additionally required and the layer structure becomes complicated. Further, the conventional alkali metal supply layer 19 is not employed, such effects may be obtained that a member of the solar cell will not become hygroscopic or soluble in water and that the reliability will not be reduced.

### (Constituent Members)

Now, specifications, etc. of the constituent members of the CIGS type solar cell 100 of the present invention will be described in detail.

### (Glass Substrate 120)

The glass substrate 120 has a function to support respective members to be laminated thereon. The substrate is not necessarily flat plate-shaped, and it may be tube-shaped. The substrate may be in any shape as long as the substrate has the function to support respective members to be laminated thereon.

As described above, the composition of the glass substrate 120 is not particularly limited so long as the glass substrate 120 contains at least one alkali metal selected from Li (lithium), Na (sodium) and K (potassium). Among the alkali metals, it is particularly preferred that Na and K are contained.

The total content of such alkali metals is preferably at least 2 mass %, more preferably at least 8 mass %, based on the glass substrate as a whole (100 mass %). Further, the upper limit of the alkali metal content is 22 mass %. If the total alkali metal content falls below 2 mass %, it becomes difficult to supply the CIGS layer 160 with a sufficient amount of the alkali metal, and further, manufacture of glass also becomes difficult.

The glass substrate 120 may, for example, be a silica glass substrate or a phosphate glass substrate.

In the case of a silica glass substrate, the glass substrate 120 may, for example, be a silica glass substrate containing an alkaline component, and it may have a composition comprising, for example, based on oxides, from 50 mass % to 75 mass %, preferably from 53 mass % to 74 mass % of SiO₂, from 1 mass % to 15 mass %, preferably from 1 mass % to 13 mass % of Al₂O₃, from 0 mass % to 2 mass %, preferably from 0 mass % to 1 mass % of B₂O₃, from 0 mass % to 10 mass %, preferably from 1.5 mass % to 8 mass % of MgO, from 0 mass % to 11 mass %, preferably from 2 mass % to 10 mass % of CaO, from 0 mass % to 12 mass %, preferably from 1 mass % to 7 mass % of SrO, from 0 mass % to 10 mass %, preferably from 0 mass % to 6 mass % of BaO, from 0 mass % to 6 mass %, preferably from 1 mass % to 5 mass % of ZrO₂, from 2 mass % to 15 mass %, preferably from 3 mass % to 14 mass % of Na₂O, and from 0 mass % to 10 mass %, preferably from 0 mass % to 8 mass % of K₂O.

The thickness of the glass substrate is, for example, within a range of from 0.5 mm to 6 mm, preferably within a range of from 1 mm to 4 mm, although it is not limited to be within such a range.

### (Rear Surface Electrode Layer 130)

As described above, the rear surface electrode layer 130 contains Mo (molybdenum) and W (tungsten), and the total W content (molar ratio (%) to Mo+W) is at most 50 mol %. In the usual case, the rear surface electrode layer 130 is provided in the form of a Mo—W alloy.

The total W content is preferably within a range of from 1 mol % to 50 mol %. If the total W content falls below 1 mol %, the effect by adding W may not be sufficiently obtained. If the total W content exceeds 50 mol %, the adhesion to the glass substrate 120 may be reduced. The total W content is more preferably from 10 mol % to 50 mol %.

The thickness of the rear surface electrode layer 130 is, for example, within a range of from 20 nm to 1,500 nm (for example, 800 nm). If the thickness of the rear surface electrode layer 130 is increased, the adhesion to the glass substrate 120 may be reduced. If the thickness of the rear surface electrode layer 130 is decreased, the electric resistance of the electrode becomes large. The thickness of the rear surface electrode layer 130 is preferably, for example, within a range of from 100 nm to 1,000 nm.

Further, as described above, the rear surface electrode layer 130 may be a laminated film comprising a Mo film and a Mo—W alloy film or comprising at least two types of Mo—W alloy films having different W contents. In the case where such a laminated film is used as the rear surface electrode layer, the total thickness may be within a range of from 20 nm to 1,500 nm. The thickness of the rear surface electrode layer 130 is, for example, within a range of from 20 nm to 1,500 nm (for example, 800 nm). If the thickness of the rear surface electrode layer 130 is increased, the adhesion to the glass substrate 120 may be reduced. If the thickness of the rear surface electrode layer 130 is decreased, the electric resistance of the electrode becomes large. The thickness of the rear surface electrode layer 130 is preferably, for example, within a range of from 100 nm to 1,000 nm.

The method for forming the rear surface electrode layer 130 is not particularly limited. The rear surface electrode layer 130 may be formed on the glass substrate 120, for example, by a sputtering method, a vapor deposition method, a gas phase film-deposition method (PVD (physical vapor deposition), CVD (chemical vapor deposition)), etc.

### (CIGS Layer 160)

The CIGS layer 160 is composed of a compound containing a group 11 element, a group 13 element and a group 16 element in the periodic table.

The CIGS layer 160 may be composed of, for example, a semiconductor having a crystal structure such as of chalcopyrite. In such a case, the CIGS layer 160 may contain at least one element M selected from the group consisting of Cu (copper), In (indium) and Ga (gallium) and at least one element A selected from the group consisting of Se (selenium) and S (sulfur). For example, as the CIGS layer 160, CuInSe₂, CuIn(Se,S)₂, Cu(In,Ga)Se₂, Cu(In,Ga)(Se,S)₂, etc. may be employed.

The thickness of the CIGS layer 160 is not particularly limited, and for example, it is within a range of from 1,000 nm to 3,000 nm, preferably from 1,300 nm to 2,300 nm.

### (Buffer Layer 170)

The buffer layer 170 is, for example, composed of a compound containing Cd (cadmium) or Zn (zinc). The compound containing Cd may, for example, be CdS (cadmium sulfate), and the compound containing Zn may, for example, be ZnO (zinc oxide), ZnS (zinc sulfate), or ZnMgO (zinc magnesium oxide).

Further, the buffer layer 170 may be composed of a plurality of semiconductor layers as shown in the construction shown in FIG. 1. In such a case, the first layer at the near side of the CIGS layer 160 is composed of CdS or a compound containing Zn described above, and the second layer at the side far from the CIGS layer 160 is composed of e.g. ZnO (zinc oxide) or a material containing ZnO.

The thickness of the buffer layer 170 is not particularly limited, and it is, for example, within a range of from 50 nm to 300 nm, preferably from 100 nm to 250 nm. (Transparent front surface electrode layer 180)

The transparent front surface electrode layer 180 has, for example, a material such as ZnO (zinc oxide) or ITO (indium tin oxide). Alternatively, the layer may have any of these materials doped with a group 13 element such as Al (aluminum). Further, the transparent front surface electrode layer 180 may be composed of a plurality of layers which are laminated.

The thickness of the transparent front surface electrode layer 180 (total thickness when it is constituted by a plurality of layers) is not particularly limited, and it is, for example, within a range of from 100 nm to 3,000 nm, preferably from 200 nm to 2,500 nm.

Here, the transparent front surface electrode layer 180 may be electrically connected with a conductive retrieving member. Such a retrieving member is preferably composed of, for example, at least one type of metal selected from the group consisting of Ni (nickel), Cr (chromium), Al (aluminum) and Ag (silver).

### EXAMPLES

Now, the present invention will be described with reference to Examples. However, it should be understood that the present invention is by no means limited to these Examples.

### Example 1

According to the following method, electrode-attached glass substrates each having a rear surface electrode layer of a different composition on a surface of the glass substrate were prepared, and their characteristics were evaluated.

### (Forming of Rear Surface Electrode Layer)

First, glass substrates for forming rear surface electrode layer were prepared. The size of each glass substrate was 50 mm high×50 mm wide×2 mm thick. Each glass substrate comprises, based on oxides, 72.8 mass % of SiO₂, 1.9 mass % of Al₂O₃, 3.7 mass % of MgO, 8.1 mass % of CaO, 13.1 mass % of Na₂O and 0.3 mass % of K₂O.

Next, on each of the glass substrates, a rear surface electrode layer was formed by a sputtering method.

As the sputtering apparatus, a sputtering apparatus (ATC1500, manufactured by AJA INTERNATIONAL) was used.

As the target, two types of targets i.e. a Mo target and a W target were used. The ratio of power applied at the time of sputtering to respective targets was adjusted to form a rear surface electrode layer having a different composition. The thickness of the rear surface electrode layer was set to be 500 nm in each case.

Sputtering was carried out in argon atmosphere, and the sputtering pressure was set to be 1.3 Pa. The film forming temperature (substrate temperature) was set to be room temperature.

In this manner, samples (No. 1 to No. 6) of electrode-attached glass substrates each provided with a rear surface electrode layer having different total W content.

The numbers of the prepared samples and the compositions of the rear surface electrode layers (20Mo-80W, etc.) are collectively shown in Table 1. In Table 1, 20Mo-80W, for example, means that the rear surface electrode layer is composed of 20 mol % of Mo and 80 mol % of W.

TABLE 1

| | Composition of | | |
|---|---|---|---|
| | rear surface | Result of | Specific |
| | electrode layer | evaluation | resistance |
| Sample | (molar ratio) | of adhesion | (μΩcm) |
| No. 1 | 100W | X | — |
| No. 2 | 20Mo—80W | X | — |
| No. 3 | 50Mo—50W | ◯ | 23.1 |
| No. 4 | 80Mo—20W | ◯ | 45.9 |
| No. 5 | 90Mo—10W | ◯ | 56.7 |
| No. 6 | 100Mo | ◯ | 71.8 |

### (Evaluation)

With respect to each of 6 types of the samples (No. 1 to No. 6) having formed a rear surface electrode layer having different composition obtained in the above step, measurement of Na diffusion behavior, adhesion test of the rear surface electrode layer and measurement of specific resistance of the rear surface electrode layer were carried out.

### (Measurement of Na Diffusion Behavior)

With respect to samples No. 1 to No. 6, measurement of Na diffusion behavior was carried out.

First, with respect to each samples No. 1 to No. 6, an ITO (indium tin oxide) film having a thickness of about 300 nm was formed on the rear surface electrode layer by a sputtering method to prepare an evaluation sample.

For film forming of the ITO film, a magnetron DC sputtering apparatus was used. For the film forming of the ITO film, a sputtering apparatus (model SPL-711V, manufactured by Tokki Corporation) was used. As the target, an ITO target doped with 10 mass % of SnO₂ was used. Further, as the sputtering gas, a mixed gas of argon and oxygen (oxygen 1 vol %) was used. The sputtering pressure was set to be 0.4 Pa. The film forming temperature (substrate temperature) was set to be room temperature.

Next, this evaluation sample was put in a nitrogen atmosphere and maintained at 550° C. for 30 minutes to permit Na in the glass substrate to diffuse into the ITO film.

Next, by employing a SIMS (Secondary Ion Mass Spectroscopy) apparatus (ADEPT1010 manufactured by Ulvac-Phi Incorporated), the ITO film of the evaluation sample was dry-etched from the outermost surface side, and detected amount of Na at this time was measured. As the primary ions, O₂⁺ ions were employed. Further, the acceleration voltage was set to be 3 kV, and the beam current was set to be 200 nA. The raster size was 300 μm×300 μm. The etching rate was set to be about 1 nm/sec.

Measurement was carried out at two points of each evaluation sample.

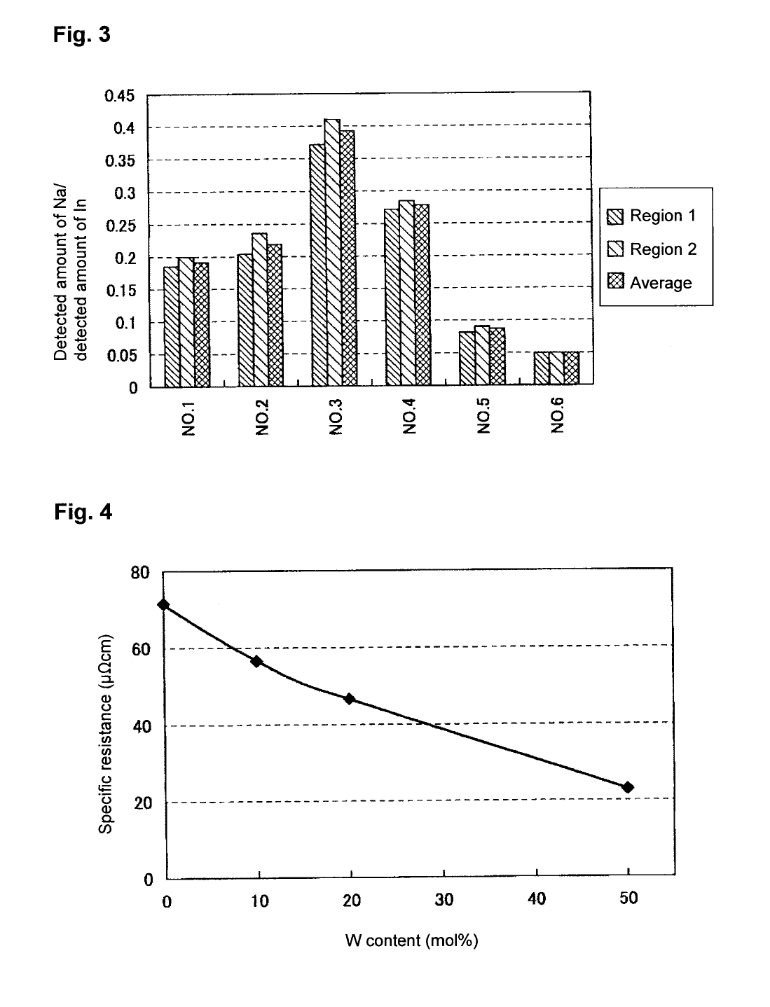

FIG. 3 shows the obtained results with respect to the evaluation samples. In FIG. 3, the horizontal axis represents samples No. 1 to No. 6 (corresponding to the total W content in the rear surface electrode layer), and the vertical axis represents the detected amount of Na measured in the evaluation. Here, the detected amount of Na shown in the vertical axis indicates the ratio of the number of counts of Na to detected indium (i.e. the number of counts of indium).

The chart of FIG. 3 shows that the amount of Na diffused into ITO from the glass via the rear surface electrode layer may be varied by changing the W content of the rear surface electrode layer. That is, it is considered that when the construction of the present invention is employed, it is possible to relatively easily control the amount of Na diffused into the CIGS layer by adjusting the total W content.

Further, as shown above, an effect of increasing the amount of Na diffused from glass can be obtained when W is present; however, if W exceeds 50 mol %, the dispersed amount of Na will be reduced. This may be related to the fact that as W is increased, the size of crystal grains constituting the Mo—W alloy as the rear surface electrode layer becomes larger. That is, if W exceeds 50 mol %, the crystal grain boundary which is considered to be a diffusion path of Na will be decreased, and as a result, the total amount of Na which can reach the ITO layer will be decreased.

### (Adhesion Test)

Next, with respect to each of samples No. 1 to No. 6, the adhesion of the rear surface electrode layer was evaluated.

An adhesive tape (CT-24, manufactured by Nichiban Co., Ltd.) was attached on the rear surface electrode layer, and the adhesion was evaluated by whether peeling of the rear surface electrode layer occurred or not when the adhesive tape was removed.

The results are shown in the column of “Result of evaluation of adhesion” in Table 1. In Table 1, “◯” represents that no peeling of the rear surface electrode layer occurred in the test, and “x” represents that peeling of the rear surface electrode layer occurred in the test.

These results show that as the total W content in the rear surface electrode layer is increased, the adhesion of the rear surface electrode layer tends to decrease. However, the results also show that when the total W content was at most 50 mol %, no peeling occurred, and the Mo—W alloys of the compositions of No. 3 to No. 6 have good adhesion to a substrate.

### (Measurement of Specific Resistance of Rear Surface Electrode Layer)

Next, with respect to each of samples No. 3 to No. 6, the specific resistance of the rear surface electrode layer was measured.

For the measurement of specific resistance, a four-terminal resistance measuring instrument (LORESTA-FP, manufactured by Mitsubishi Petrochemical Co., Ltd.) was used.

The results are shown in the column of “Specific resistance” in Table 1 and FIG. 4. The chart of FIG. 4 shows that as the W amount in the rear surface electrode layer is increased, the specific resistance of the layer tends to decrease.

In particular, as compared with sample No. 6 containing no W, the specific resistance of sample No. 3 containing 50 mol % of W was reduced to about one third. This shows that it is possible to reduce the specific resistance of the rear surface electrode layer by adding W.

The specific resistance of the rear surface electrode layer has a major impact on the characteristics of a solar cell, and thus in the usual case, the specific resistance of the rear surface electrode layer is preferably as small as possible. From this point of view, it is expected that when a Mo layer containing W is employed as a rear surface electrode layer, the specific resistance of the rear surface electrode layer is suppressed, and the characteristics of the solar cell is thereby improved.

### Example 2

Now, Example 2 of the present invention will be described.

According to the following method, electrode-attached glass substrates each having a rear surface electrode layer of a different composition on a surface of the glass substrate were prepared, and their characteristics were evaluated.

### (Forming of Rear Surface Electrode Layer)

First, glass substrates for forming rear surface electrode layer were prepared. The size of each glass substrate was 50 mm high×50 mm wide×2.8 mm thick. Each glass substrate comprises, based on oxides, 57.7 mass % of SiO₂, 6.9 mass % of Al₂O₃, 2 mass % of MgO, 5 mass % of CaO, 7 mass % of SrO, 8 mass % of BaO, 3 mass % of ZrO₂, 4.3 mass % of Na₂O and 6 mass % of K₂O.

Next, on each of the glass substrates, a rear surface electrode layer was formed by a sputtering method.

As the sputtering apparatus, a sputtering apparatus (ATC1500, manufactured by AJA INTERNATIONAL) was used

As the target, two types of targets i.e. a Mo target and a W target were used. The ratio of power applied at the time of sputtering to respective targets was adjusted to form, first, a 100 nm film of a rear surface electrode layer of 50Mo-50W having a composition ratio of 50 mol % of Mo and 50 mol % of W. The atmosphere was argon gas, and the sputtering pressure was set to be 1.3 Pa, and the film forming temperature (substrate temperature) was set to be room temperature. Next, a 400 nm Mo film was formed thereon to obtain the total thickness of 500 nm.

The atmosphere of film formation of Mo film was argon gas, and the sputtering pressure was set to be 0.4 Pa. Further, the film forming temperature (substrate temperature) was set to be room temperature. In this manner, a sample (No. 7) of an electrode-attached glass substrate provided with a rear surface electrode layer composed of a 50Mo-50W layer and a Mo layer was obtained. The specific resistance of this sample was 16 μΩcm, and the adhesion was good.

Further, for comparison purpose, a sample having a 500 nm Mo film formed was prepared to obtain a sample (No. 8) of an electrode-attached glass substrate provided with a rear surface electrode layer of a Mo single layer.

The atmosphere was argon gas, and the sputtering pressure was set to be 0.4 Pa. Further, the film forming temperature (substrate temperature) was set to be room temperature. The specific resistance of this sample was 19 μΩcm, and the adhesion was good.

### (Measurement of Diffusion Behavior of Na and K)

With respect to samples No. 7 and No. 8, measurement of diffusion behavior of Na and K was carried out.

First, with respect to each of samples No. 7 and No. 8, an ITO (indium tin oxide) film having a thickness of about 300 nm was formed on the rear surface electrode layer by a sputtering method to prepare an evaluation sample. The film forming condition for ITO was the same as in Example 1.

Next, this evaluation sample was put in a nitrogen atmosphere and maintained at 580° C. for 30 minutes to permit Na in the glass substrate to diffuse into the ITO film.

Next, under the same condition as in Example 1, by employing a SIMS apparatus, the ITO film of the evaluation sample was dry-etched from the outermost surface side, and Na amount and K amount detected at this time were measured.

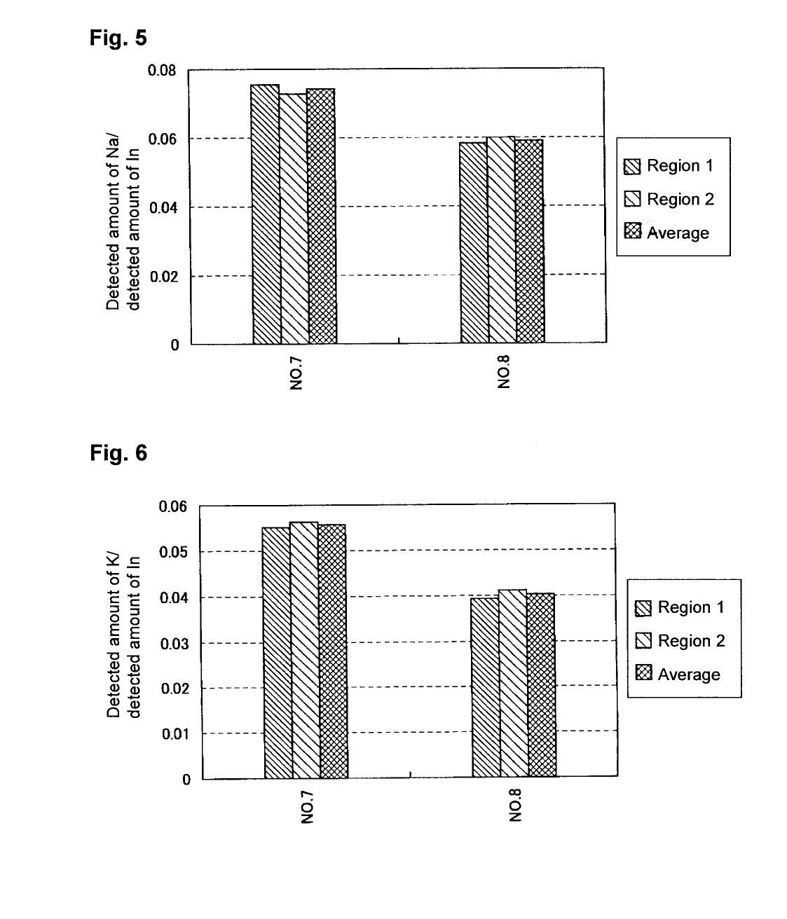

FIGS. 5 and 6 show the obtained results with respect to the evaluation samples. In FIG. 5, the horizontal axis represents samples No. 7 and No. 8, and the vertical axis represents the detected amount of Na measured in the evaluation. Here, the detected amount of Na shown in the vertical axis indicates the ratio of the number of counts of Na to detected indium (i.e. the number of counts of indium). In FIG. 6, the horizontal axis represents samples No. 7 and No. 8, and the vertical axis represents the detected amount of K measured in the evaluation. Here, the detected amount of K shown in the vertical axis indicates the ratio of the number of counts of K to detected indium (i.e. the number of counts of indium).

FIG. 5 and FIG. 6 show that even when employing a laminated film of a Mo film and a Mo—W alloy film, it is possible to vary the Na amount and the K amount diffused from the glass into ITO via the rear surface electrode layer.

That is, in the construction of the present invention, a Mo film and a Mo—W alloy film may be used in combination. As compared with FIG. 3, the increasing rate of Na diffusion is low. It is considered that this is because a part of Na diffused from the Mo—W alloy film having a high level of ability to promote the diffusion of Na is blocked by the Mo film having a low level of ability to diffuse Na. These test results show that it is possible to control the diffused amount of Na by adjusting the thickness ratio of the Mo film and the Mo—W alloy film.

It is considered that by employing such a construction, it is possible to relatively easily control the amount of Na diffused into the CIGS layer by adjusting the thickness ratio of the Mo film and the Mo—W alloy film or the thickness ratio of two types of Mo—W alloy films having different W contents. Even when the composition of Mo—W as a sputtering target is fixed, the diffused amount of the alkali metal can be controlled by the thickness ratio of the laminated films, whereby it is possible to control the amount of Na diffused into the CIGS layer more easily as compared with a case where the diffused amount of Na is controlled by preparing targets having various compositions.

### INDUSTRIAL APPLICABILITY

The CIGS solar cell of the present invention is capable of diffusing a desired amount of an alkali metal into the CIGS layer without e.g. complicating its layer structure, and it is useful as a CIGS type solar cell having characteristics such as high energy conversion efficiency and small deterioration in efficiency by light irradiation.

This application is a continuation of PCT Application No. PCT/JP2011/063615, filed on Jun. 14, 2011, which is based upon and claims the benefit of priority from Japanese Patent Application No. 2010-139923 filed on Jun. 18, 2010. The contents of those applications are incorporated herein by reference in its entirety.

### REFERENCE SYMBOLS

10: Conventional CIGS type solar cell
11: Insulative substrate
12a: First conductive layer
12b: Second conductive layer
13: Light-absorber layer
14: First semiconductor layer
15: Second semiconductor layer
16: Transparent conductive layer
17, 18: Retrieving electrode
19: Alkali metal supply layer
90: Incident direction of light
100: CIGS type solar cell of the present invention
120: Glass substrate
130: Rear surface electrode layer
160: CIGS layer
170: Buffer layer
180: Transparent front surface electrode layer
190: Incident direction of light

What is claimed is:

1. A CIGS type solar cell comprising a glass substrate, a rear surface electrode layer provided on the glass substrate, a CIGS layer provided on the rear surface electrode layer, a buffer layer provided on the CIGS layer and a transparent front surface electrode layer provided on the buffer layer, wherein the rear surface electrode layer contains Mo (molybdenum) and W (tungsten), and the total W content in the rear surface electrode layer is at most 50 mol %.

2. The solar cell according to claim 1, wherein the total W content in the rear surface electrode layer is at least 1 mol %.

3. The solar cell according to claim 1, wherein the rear surface electrode layer is a laminated film consisting essentially of a Mo film and a Mo—W alloy film or a laminated film consisting essentially of at least two types of Mo—W alloy films having different W contents.

4. The solar cell according to claim 1, wherein the rear surface electrode layer has a thickness within a range of from 20 nm to 1,500 nm.

5. The solar cell according to claim 1, wherein the glass substrate is a silica glass substrate comprising, based on oxides, from 50 mass % to 75 mass % of SiO₂, said glass substrate containing from 2 mass % to 15 mass % of Na₂O and from 0 mass % to 10 mass % of K₂O.

6. The solar cell according to claim 1, wherein the glass substrate comprises, based on oxides, from 1 mass % to 15 mass % of Al₂O₃, from 0 mass % to 2 mass % of B₂O₃, from 0 mass % to 10 mass % of MgO, from 0 mass % to 11 mass % of CaO, from 0 mass % to 12 mass % of SrO, from 0 mass % to 10 mass % of BaO, from 0 mass % to 6 mass % of ZrO₂, from 50 mass % to 75 mass % of SiO₂, from 2 mass % to 15 mass % of Na₂O and from 0 mass % to 10 mass % of K₂O.

7. An electrode-attached glass substrate for a CIGS type solar cell, which comprises a glass substrate and a rear surface electrode layer provided on a first surface of the glass substrate, wherein the rear surface electrode layer contains Mo (molybdenum) and W (tungsten), and the total W content in the rear surface electrode layer is at most 50 mol %.

8. The electrode-attached glass substrate according to claim 7, wherein the total W content in the rear surface electrode layer is at least 1 mol %.

9. The electrode-attached glass substrate according to claim 7, wherein the rear surface electrode layer is a laminated film comprising a Mo film and a Mo—W alloy film or a laminated film comprising at least two types of Mo—W alloy films having different W contents.

10. The electrode-attached glass substrate according to claim 7, wherein the rear surface electrode layer has a thickness within a range of from 20 nm to 1,500 nm.

11. The electrode-attached glass substrate according to claim 7, wherein the glass substrate is a silica glass substrate comprising, based on oxides, from 50 mass % to 75 mass % of SiO₂, said glass substrate containing from 2 mass % to 15 mass % of Na₂O and from 0 mass % to 10 mass % of K₂O.

12. The electrode-attached glass substrate according to claim 7, wherein the glass substrate comprises, based on oxides, from 1 mass % to 15 mass % of Al₂O₃, from 0 mass % to 2 mass % of B₂O₃, from 0 mass % to 10 mass % of MgO, from 0 mass % to 11 mass % of CaO, from 0 mass % to 12 mass % of SrO, from 0 mass % to 10 mass % of BaO, from 0 mass % to 6 mass % of ZrO₂, from 50 mass % to 75 mass % of SiO₂, from 2 mass % to 15 mass % of Na₂O and from 0 mass % to 10 mass % of K₂O.
